(19) United States
(12) Patent Application Publication
(10) Pub. No.: US 2025/0054555 A1
(43) Pub. Date: Feb. 13, 2025

(54) FIVE LEVEL CELL PROGRAM ALGORITHM WITH APPENDED BIT LEVEL ERASE FOR ADDITIONAL THRESHOLD VOLTAGE BUDGET

(71) Applicant: Western Digital Technologies, Inc., San Jose, CA (US)

(72) Inventors: Ming Wang, Shanghai (CN); Liang Li, Shanghai (CN); Xuan Tian, Shanghai (CN)

(73) Assignee: Western Digital Technologies, Inc., San Jose, CA (US)

(21) Appl. No.: 18/232,010

(22) Filed: Aug. 9, 2023

(51) Int. Cl. G11C 16/34; G11C 11/56; G11C 16/04; G11C 16/10; G11C 16/16

(52) U.S. Cl. CPC G11C 16/3427; G11C 11/5628; G11C 11/5635; G11C 11/5671; G11C 16/0483; G11C 16/107; G11C 16/16; G11C 16/3459

(57) ABSTRACT

A memory apparatus and method of operation are provided. The apparatus includes memory cells each connected to one of a plurality of word lines and configured to store a threshold voltage. A control means is coupled to the plurality of word lines and is configured to apply at least one programming pulse of a program voltage to selected ones of the plurality of word lines during at least one programming loop of a programming operation. The control means is also configured to reduce the threshold voltage of the memory cells targeted for an erased state during a bit-level erase operation following the programming operation.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory devices have become more popular for use in various electronic devices. For example, non-volatile semiconductor memory is used in cellular telephones, digital cameras, personal digital assistants, mobile computing devices, non-mobile computing devices and other devices.

A charge-storing material such as a floating gate or a charge-trapping material can be used in such memory devices to store a charge which represents a data state. A charge-trapping material can be arranged vertically in a three-dimensional (3D) stacked memory structure, or horizontally in a two-dimensional (2D) memory structure. One example of a 3D memory structure is the Bit Cost Scalable (BiCS) architecture which comprises a stack of alternating conductive and dielectric layers.

A memory device includes memory cells which may be arranged in strings, for instance, where select gate transistors are provided at the ends of the string to selectively connect a channel of the string to a source line or bit line. However, various challenges are presented in operating such memory devices. For example, some memory cells may be disturbed during a programming operation.

### SUMMARY

This section provides a general summary of the present disclosure and is not a comprehensive disclosure of its full scope or all of its features and advantages.

An object of the present disclosure is to provide a memory apparatus and a method of operating the memory apparatus that address and overcome the above-noted shortcomings.

Accordingly, it is an aspect of the present disclosure to provide a memory apparatus including memory cells each connected to one of a plurality of word lines and configured to store a threshold voltage. A control means is coupled to the plurality of word lines and is configured to apply at least one programming pulse of a program voltage to selected ones of the plurality of word lines during at least one programming loop of a programming operation. The control means is also configured to reduce the threshold voltage of the memory cells targeted for an erased state during a bit-level erase operation following the programming operation.

According to another aspect of the disclosure, a controller in communication with a memory apparatus including memory cells each connected to one of a plurality of word lines is provided. The memory cells are configured to store a threshold voltage. The controller is configured to instruct the memory apparatus to apply at least one programming pulse of a program voltage to selected ones of the plurality of word lines during at least one programming loop of a programming operation. The controller is also configured to instruct the memory apparatus to reduce the threshold voltage of the memory cells targeted for an erased state during a bit-level erase operation following the programming operation.

According to an additional aspect of the disclosure a method of operating a memory apparatus is provided. The memory apparatus includes memory cells each connected to one of a plurality of word lines. The memory cells are configured to store a threshold voltage. The method includes the step of applying at least one programming pulse of a program voltage to selected ones of the plurality of word lines during at least one programming loop of a programming operation. The method also includes the step of reducing the threshold voltage of the memory cells targeted for an erased state during a bit-level erase operation following the programming operation.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a block diagram of an example memory apparatus or device according to aspects of the disclosure;

FIG. 1B depicts an example memory cell according to aspects of the disclosure;

FIG. 1C depicts an example of the temperature-sensing circuit of FIG. 1A according to aspects of the disclosure;

FIG. 2 is a block diagram of the example memory device, depicting additional details of the controller according to aspects of the disclosure;

FIG. 3 is a perspective view of a memory device comprising a set of blocks in an example 3D configuration of the memory structure of FIG. 1 according to aspects of the disclosure;

FIG. 4 depicts an example cross-sectional view of a portion of one of the blocks of FIG. 3 according to aspects of the disclosure;

FIG. 5 depicts a plot of memory hole/pillar diameter in the stack of FIG. 4 according to aspects of the disclosure;

FIG. 6 depicts a close-up view of a region of the stack of FIG. 4 according to aspects of the disclosure;

FIG. 7A depicts an example view of NAND strings in sub-blocks in a 3D configuration which is consistent with FIG. 4 according to aspects of the disclosure;

FIG. 7B depicts word line and SGD layers in an example set of blocks which is consistent with FIG. 4 according to aspects of the disclosure;

FIG. 8A depicts an example threshold voltage (Vth) distribution of memory cells, where eight data states are used, in a first read condition compared to a second read condition according to aspects of the disclosure;

FIG. 8B depicts example bit sequences for lower, middle and upper pages of data, and associated read voltages, for the Vth distributions of FIG. 8A according to aspects of the disclosure;

FIG. 9 depicts a waveform of an example programming operation according to aspects of the disclosure;

FIG. 10 shows threshold voltage distributions for quad-level cells after an erase operation, after programming, and after a bit-level erase operation according to aspects of the disclosure;

FIG. 11 shows a cross-sectional view of a portion of an example memory apparatus and illustrates voltages in a channel of a string or memory hole including the memory cells targeted for the erased state and another memory hole including the memory cells not targeted for the erased state according to aspects of the disclosure;

FIG. 12 shows voltage levels and timing during the bit-level erase operation and pre-charging preceding the bit-level erase operation for the bit lines, word lines, and select gate transistors according to aspects of the disclosure; and

FIGS. 13 and 14 illustrate steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of operation of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

In some memory devices, memory cells are joined to one another such as in NAND strings in a block or sub-block. Each NAND string comprises a number of memory cells connected in series between one or more drain-side SG transistors (SGD transistors), on a drain-side of the NAND string which is connected to a bit line, and one or more source-side SG transistors (SGS transistors), on a source-side of the NAND string which is connected to a source line. Further, the memory cells can be arranged with a common control gate line (e.g., word line) which acts a control gate. A set of word lines extends from the source side of a block to the drain side of a block. Memory cells can be connected in other types of strings and in other ways as well.

The memory cells can include data memory cells, which are eligible to store user data, and dummy or non-data memory cells which are ineligible to store user data. A dummy word line is connected to a dummy memory cell. One or more dummy memory cells may be provided at the drain and/or source ends of a string of memory cells to provide a gradual transition in channel gradient.

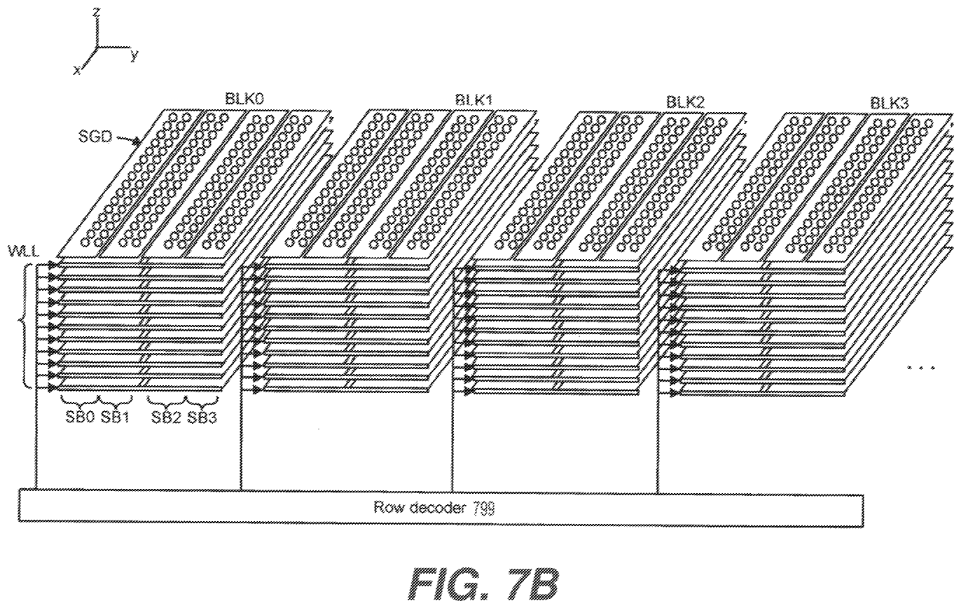

During a programming operation, the memory cells are programmed according to a word line programming order. For example, the programming may start at the word line at the source side of the block and proceed to the word line at the drain side of the block. In one approach, each word line is completely programmed before programming a next word line. For example, a first word line, WL0, is programmed using one or more programming passes until the programming is completed. Next, a second word line, WL1, is programmed using one or more programming passes until the programming is completed, and so forth. A programming pass may include a set of increasing program voltages which are applied to the word line in respective program loops or program-verify iterations, such as depicted in FIG. 9. Verify operations may be performed after each program voltage to determine whether the memory cells have completed programming. When programming is completed for a memory cell, it can be locked out from further programming while programming continues for other memory cells in subsequent program loops.

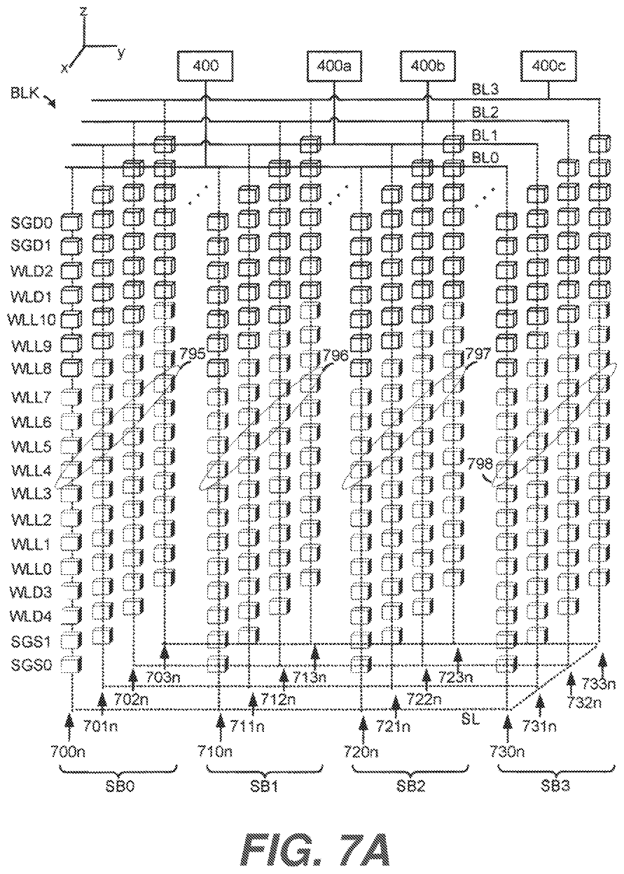

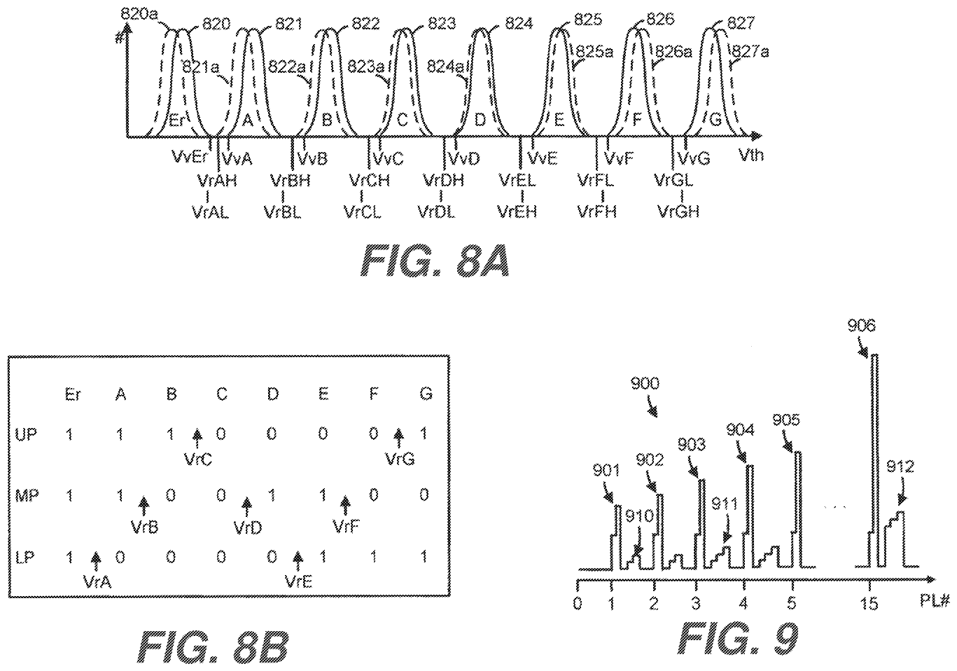

Each memory cell may be associated with a data state according to its threshold voltage. Based on its data state, a memory cell will either remain in the erased state or be programmed to a programmed data state. For example, in a one bit per cell memory device, there are two data states including the erased state and the programmed state. In a two-bit per cell memory device, there are four data states including the erased state and three higher data states referred to as the A, B and C data states. In a three-bit per cell memory device, there are eight data states including the erased state and seven higher data states referred to as the A, B, C, D, E, F and G data states (see FIG. 8A). In a four-bit per cell memory device (quad-level cells or QLC), there are sixteen data states including the erased state and fifteen higher data states. The data states may be referred to as the S0, S1, S2, S3, S4, S5, S6, S7, S8, S9, S10, S11, S12, S13, S14 and S15 data states where S0 is the erased state (see e.g., FIG. 10). In a five-bit per cell memory device (five-level cells or PLC), there are thirty two data states including the erased state and thirty one higher data states. However, the program threshold voltage budget (i.e., spacing of the threshold voltage distributions from one another) becomes more limited as the number of states increases. Furthermore, for QLC and PLC memory devices, programming may include a comparatively increased number of program loops, resulting in increased program disturb for data states associated with relatively lower threshold voltages (i.e., lower data states). Such program disturb can result in decreased memory cell reliability. Techniques provided herein address the above and other issues.

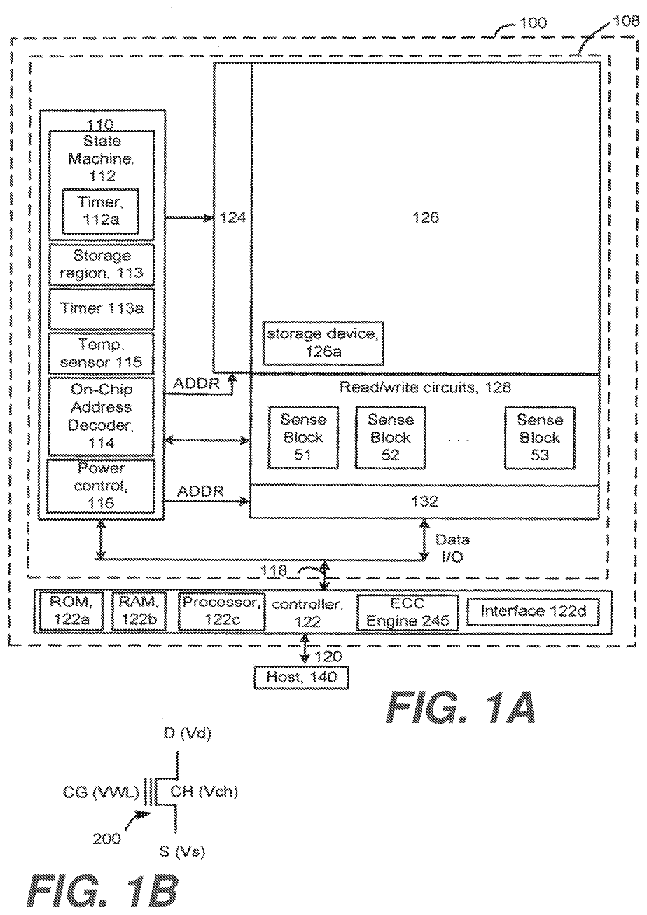

FIG. 1A is a block diagram of an example memory device. The memory device 100, such as a non-volatile storage system, may include one or more memory die 108. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks 51, 52, . . . , 53 (sensing circuitry) and allow a page of memory cells to be read or programmed in parallel. Typically a controller 122 is included in the same memory device 100 (e.g., a removable storage card) as the one or more memory die 108. The controller may be separate from the memory die. Commands and data are transferred between the host 140 and controller 122 via a data bus 120, and between the controller and the one or more memory die 108 via lines 118.

The memory structure can be 2D or 3D. The memory structure may comprise one or more array of memory cells including a 3D array. The memory structure may comprise a monolithic 3D memory structure in which multiple memory levels are formed above (and not in) a single substrate, such as a wafer, with no intervening substrates. The memory structure may comprise any type of non-volatile memory that is monolithically formed in one or more physical levels of arrays of memory cells having an active area disposed above a silicon substrate. The memory structure may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations. The state machine may include a clock 112a to determine an elapsed time since a last sensing operation, as discussed further below. A storage region 113 may be provided, e.g., for sets of read voltage, as described further below. Generally, the storage region may store operational parameters and software/code. A timer 113a may also be used to determine timing of predetermined refresh read voltage pulses to word lines, described in more detail below, for example. A temperature sensor 115 may also be provided.

In one embodiment, the state machine is programmable by the software. In other embodiments, the state machine does not use software and is completely implemented in hardware (e.g., electrical circuits).

The on-chip address decoder 114 provides an address interface between that used by the host or a memory controller to the hardware address used by the decoders 124 and 132. The power control module 116 controls the power and voltages supplied to the word lines, select gate lines and bit lines during memory operations. It can include drivers for word lines, SGS and SGD transistors and source lines. The sense blocks can include bit line drivers, in one approach. An SGS transistor is a select gate transistor at a source end of a NAND string, and an SGD transistor is a select gate transistor at a drain end of a NAND string.

In some implementations, some of the components can be combined. In various designs, one or more of the components (alone or in combination), other than memory structure 126, can be thought of as at least one control circuit which is configured to perform the techniques described herein including the steps of the processes described herein. For example, a control circuit may include any one of, or a combination of, control circuitry 110, state machine 112, decoders 114 and 132, power control module 116, sense blocks 51, 52, . . . , 53, read/write circuits 128, controller 122, and so forth.

The off-chip controller 122 (which in one embodiment is an electrical circuit) may comprise a processor 122c, storage devices (memory) such as ROM 122a and RAM 122b and an error-correction code (ECC) engine 245. The ECC engine can correct a number of read errors.

A memory interface 122d may also be provided. The memory interface, in communication with ROM, RAM and processor, is an electrical circuit that provides an electrical interface between controller and memory die. For example, the memory interface can change the format or timing of signals, provide a buffer, isolate from surges, latch I/O and so forth. The processor can issue commands to the control circuitry 110 (or any other component of the memory die) via the memory interface 122 d.

The storage device comprises code such as a set of instructions, and the processor is operable to execute the set of instructions to provide the functionality described herein. Alternatively or additionally, the processor can access code from a storage device 126a of the memory structure, such as a reserved area of memory cells in one or more word lines.

For example, code can be used by the controller to access the memory structure such as for programming, read and erase operations. The code can include boot code and control code (e.g., a set of instructions). The boot code is software that initializes the controller during a booting or startup process and enables the controller to access the memory structure. The code can be used by the controller to control one or more memory structures. Upon being powered up, the processor 122c fetches the boot code from the ROM 122a or storage device 126a for execution, and the boot code initializes the system components and loads the control code into the RAM 122b. Once the control code is loaded into the RAM, it is executed by the processor. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below, and provide the voltage waveforms including those discussed further below. A control circuit can be configured to execute the instructions to perform the functions described herein.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a 2D memory structure or a 3D memory structure.

In a 2D memory structure, the semiconductor memory elements are arranged in a single plane or a single memory device level. Typically, in a 2D memory structure, memory elements are arranged in a plane (e.g., in an x-y direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A 3D memory array is arranged so that memory elements occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, i.e., in the y direction) with each column having multiple memory elements. The columns may be arranged in a 2D configuration, e.g., in an x-y plane, resulting in a 3D arrangement of memory elements with elements on multiple vertically stacked memory planes. Other configurations of memory elements in three dimensions can also constitute a 3D memory array.

By way of non-limiting example, in a 3D NAND memory array, the memory elements may be coupled together to form a NAND string within a single horizontal (e.g., x-y) memory device level. Alternatively, the memory elements may be coupled together to form a vertical NAND string that traverses across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

Typically, in a monolithic 3D memory array, one or more memory device levels are formed above a single substrate. Optionally, the monolithic 3D memory array may also have one or more memory layers at least partially within the single substrate. As a non-limiting example, the substrate may include a semiconductor such as silicon. In a monolithic 3D array, the layers constituting each memory device level of the array are typically formed on the layers of the underlying memory device levels of the array. However, layers of adjacent memory device levels of a monolithic 3D memory array may be shared or have intervening layers between memory device levels.

2D arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic 3D memory arrays. Further, multiple 2D memory arrays or 3D memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this technology is not limited to the 2D and 3D exemplary structures described but covers all relevant memory structures within the spirit and scope of the technology as described herein and as understood by one of skill in the art.

FIG. 1B depicts an example memory cell 200. The memory cell comprises a control gate CG which receives a word line voltage Vwl, a drain at a voltage Vd, a source at a voltage Vs and a channel at a voltage Vch.

FIG. 1C depicts an example of the temperature-sensing circuit 115 of FIG. 1A. The circuit includes pMOSFETs 131a, 131b and 134, bipolar transistors 133a and 133b and resistors R1, R2 and R3. I1, I2 and I3 denote currents. Voutput is a temperature-based output voltage provided to an analog-to-digital (ADC) converter 129. Vbg is a temperature-independent voltage. A voltage level generation circuit 135 uses Vbg to set a number of voltage levels. For example, a reference voltage may be divided down into several levels by a resistor divider circuit.

The ADC compares Voutput to the voltage levels and selects a closest match among the voltage levels, outputting a corresponding digital value (VTemp) to the processor. This is data indicating a temperature of the memory device. ROM fuses 123 store data which correlates the matching voltage level to a temperature, in one approach. The processor then uses the temperature to set temperature-based parameters in the memory device.

Vbg, is obtained by adding the base-emitter voltage (Vbe) across the transistor 131b and the voltage drop across the resistor R2. The bipolar transistor 133a has a larger area (by a factor N) than the transistor 133b. The PMOS transistors 131a and 131b are equal in size and are arranged in a current mirror configuration so that the currents 11 and 12 are substantially equal. We have Vbg=Vbe+R2×I2 and I1=Ve/R1 so that I2=Ve/R1. As a result, Vbg=Vbe+R2×kT In(N)/R1×q, where T is temperature, k is Boltzmann's constant and q is a unit of electric charge. The source of the transistor 134 is connected to a supply voltage VDDSAVdd and the node between the transistor's drain and the resistor R3 is the output voltage, Voutput. The gate of the transistor 134 is connected to the same terminal as the gates of transistors 131a and 131b and the current through the transistor 134 mirrors the current through the transistors 131a and 131b.

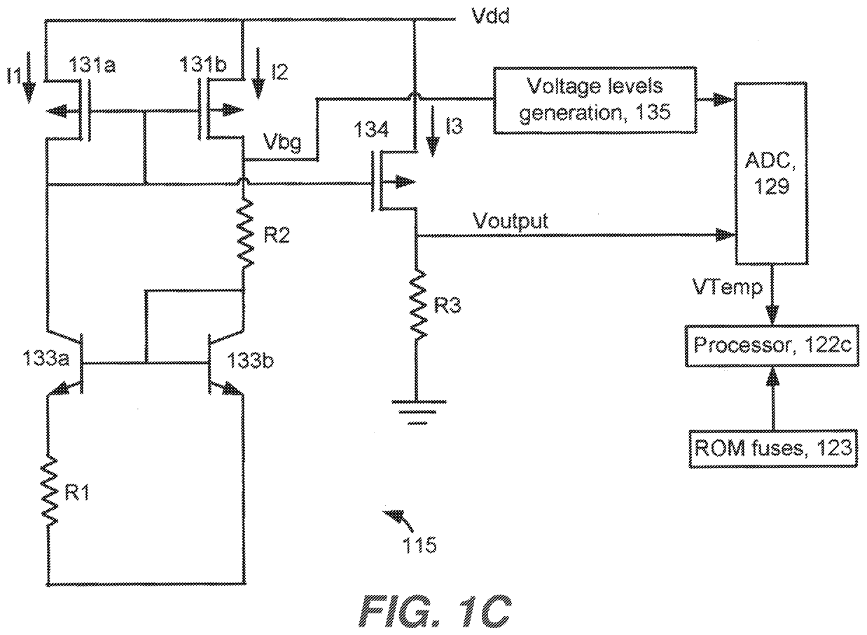

FIG. 2 is a block diagram of the example memory device 100, depicting additional details of the controller 122. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between the controller 122 and non-volatile memory die 108 may be any suitable flash interface. In one embodiment, memory device 100 may be a card based system, such as a secure digital (SD) or a micro secure digital (micro-SD) card. In an alternate embodiment, the memory system may be part of an embedded memory system. For example, the flash memory may be embedded within the host, such as in the form of a solid state disk (SSD) drive installed in a personal computer.

In some embodiments, the memory device 100 includes a single channel between the controller 122 and the non-volatile memory die 108, the subject matter described herein is not limited to having a single memory channel.

The controller 122 includes a front end module 208 that interfaces with a host, a back end module 210 that interfaces with the one or more non-volatile memory die 108, and various other modules that perform functions which will now be described in detail.

The components of the controller may take the form of a packaged functional hardware unit (e.g., an electrical circuit) designed for use with other components, a portion of a program code (e.g., software or firmware) executable by a processor, e.g., microprocessor, or processing circuitry that usually performs a particular function of related functions, or a self-contained hardware or software component that interfaces with a larger system, for example. For example, each module may include an Application Specific Integrated Circuit (ASIC), a Field Programmable Gate Array (FPGA), a circuit, a digital logic circuit, an analog circuit, a combination of discrete circuits, gates, or any other type of hardware or combination thereof. Alternatively or in addition, each module may include software stored in a processor readable device (e.g., memory) to program a processor for the controller to perform the functions described herein. The architecture depicted in FIG. 2 is one example implementation that may (or may not) use the components of the controller 122 depicted in FIG. 1A (e.g., RAM, ROM, processor, interface).

The controller 122 may include recondition circuitry 212, which is used for reconditioning memory cells or blocks of memory. The reconditioning may include refreshing data in its current location or reprogramming data into a new word line or block as part of performing erratic word line maintenance, as described below.

Referring again to modules of the controller 122, a buffer manager/bus controller 214 manages buffers in random access memory (RAM) 216 and controls the internal bus arbitration of Controller 122. The RAM may include DRAM and/or SRAM. DRAM or Dynamic Random Access Memory is a type of semiconductor memory in which the memory is stored in the form of a charge. Each memory cell in a DRAM is made of a transistor and a capacitor. The data is stored in the capacitor. Capacitors loose charge due to leakage and hence DRAMs are volatile devices. To keep the data in the memory, the device must be regularly refreshed. In contrast, SRAM or Static Random Access Memory will retain a value as long as power is supplied.

A read only memory (ROM) 218 stores system boot code. Although illustrated in FIG. 2 as being located separately from the controller, in other embodiments, one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction controller (ECC) engine 224 that encodes the data bytes received from the host, and decodes and error corrects the data bytes read from the non-volatile memory. A command sequencer 226 generates command sequences, such as program and erase command sequences, to be transmitted to non-volatile memory die 108. A RAID (Redundant Array of Independent Dies) module 228 manages generation of RAID parity and recovery of failed data. The RAID parity may be used as an additional level of integrity protection for the data being written into the memory device 100. In some cases, the RAID module 228 may be a part of the ECC engine 224. Note that the RAID parity may be added as an extra die or dies as implied by the common name, but it may also be added within the existing die, e.g. as an extra plane, or extra block, or extra word lines within a block. A memory interface 230 provides the command sequences to non-volatile memory die 108 and receives status information from the non-volatile memory die. A flash control layer 232 controls the overall operation of back end module 210.

Additional components of memory device 100 include media management layer 238, which performs wear leveling of memory cells of non-volatile memory die 108. The memory system also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The Flash Translation Layer (FTL) or Media Management Layer (MML) 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the memory structure 126, e.g., flash memory, of die 108. The MML 238 may be needed because: 1) the flash memory may have limited endurance; 2) the flash memory may only be written in multiples of pages; and/or 3) the flash memory may not be written unless it is erased as a block. The MML 238 understands these potential limitations of the flash memory which may not be visible to the host. Accordingly, the MML 238 attempts to translate the writes from host into writes into the flash memory. Erratic bits may be identified and recorded using the MML 238. This recording of erratic bits can be used for evaluating the health of blocks and/or word lines (the memory cells on the word lines).

The controller 122 may interface with one or more memory dies 108. In one embodiment, the controller and multiple memory dies (together comprising the memory device 100) implement a solid state drive (SSD), which can emulate, replace or be used instead of a hard disk drive inside a host, as a network-attached storage (NAS) device, and so forth. Additionally, the SSD need not be made to work as a hard drive.

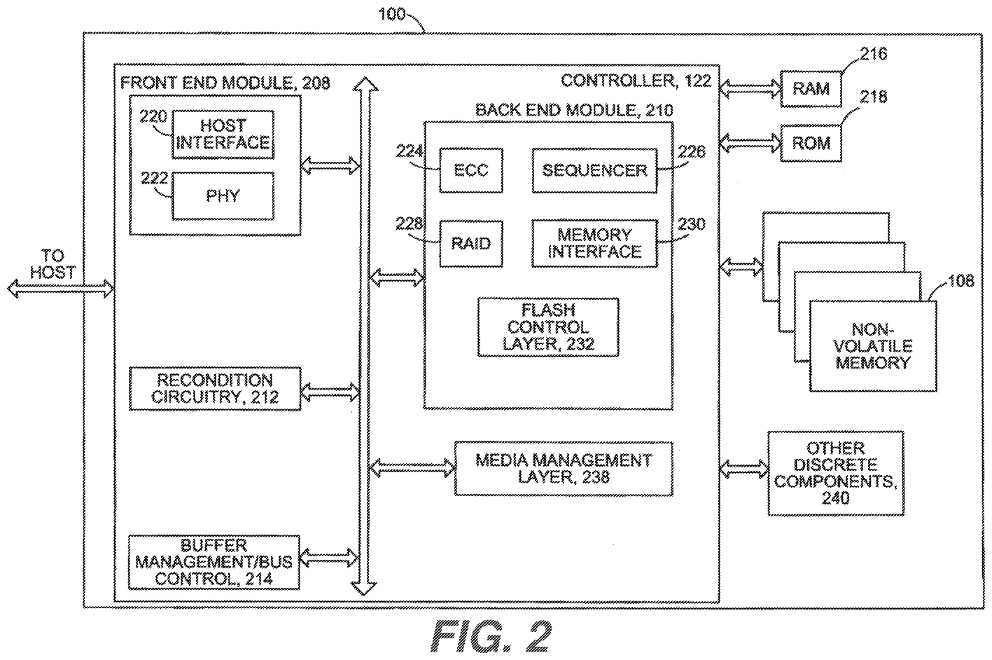

FIG. 3 is a perspective view of a memory device 600 comprising a set of blocks in an example 3D configuration of the memory structure 126 of FIG. 1A. On the substrate are example blocks BLK0, BLK1, BLK2 and BLK3 of memory cells (storage elements) and a peripheral area 604 with circuitry for use by the blocks. For example, the circuitry can include voltage drivers 605 which can be connected to control gate layers of the blocks. In one approach, control gate layers at a common height in the blocks are commonly driven. The substrate 601 can also carry circuitry under the blocks, along with one or more lower metal layers which are patterned in conductive paths to carry signals of the circuitry. The blocks are formed in an intermediate region 602 of the memory device. In an upper region 603 of the memory device, one or more upper metal layers are patterned in conductive paths to carry signals of the circuitry. Each block comprises a stacked area of memory cells, where alternating levels of the stack represent word lines. In one possible approach, each block has opposing tiered sides from which vertical contacts extend upward to an upper metal layer to form connections to conductive paths. While four blocks are depicted as an example, two or more blocks can be used, extending in the x- and/or y-directions.

In one possible approach, the blocks are in a plane, and the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device. The blocks could also be arranged in multiple planes.

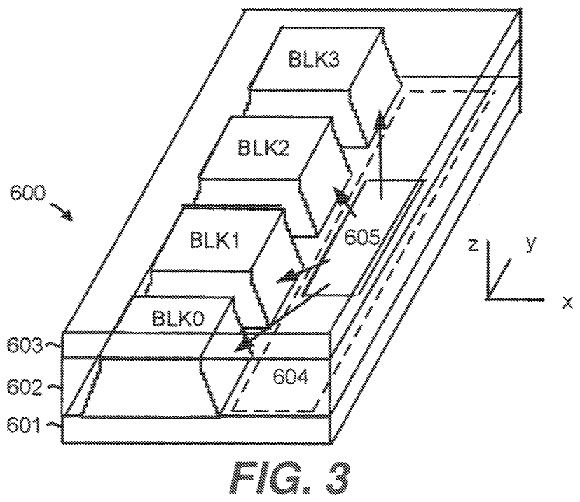

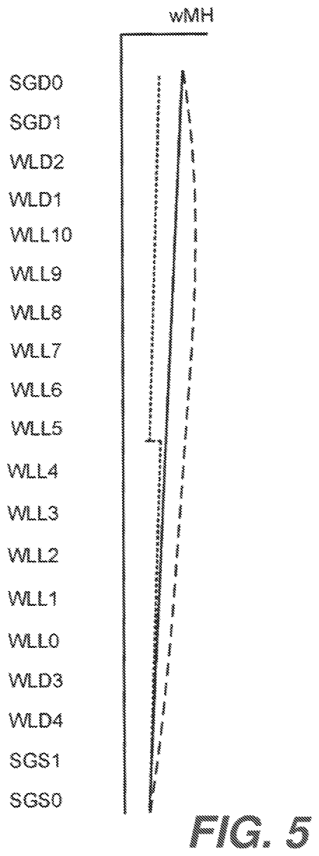

FIG. 4 depicts an example cross-sectional view of a portion of one of the blocks of FIG. 3. The block comprises a stack 616 of alternating conductive and dielectric layers. In this example, the conductive layers comprise two SGD layers, two SGS layers and four dummy word line layers (or word lines) WLD1, WLD2, WLD3 and WLD4, in addition to data word line layers (or word lines) WLL0-WLL10. The dielectric layers are labelled as DL0-DL19. Further, regions of the stack which comprise NAND strings NS1 and NS2 are depicted. Each NAND string encompasses a memory hole 618 or 619 which is filled with materials which form memory cells adjacent to the word lines. A region 622 of the stack is shown in greater detail in FIG. 6.

The stack includes a substrate 611. In one approach, a portion of the source line SL comprises an n-type source diffusion layer 611a in the substrate which is in contact with a source end of each string of memory cells in a block. The n-type source diffusion layer 611a is formed in a p-type well region 611b, which in turn is formed in an n-type well region 611c, which in turn is formed in a p-type semiconductor substrate 611d, in one possible implementation. The n-type source diffusion layer may be shared by all of the blocks in a plane, in one approach.

NS1 has a source-end 613 at a bottom 616b of the stack and a drain-end 615 at a top 616a of the stack. Local interconnects, such as local interconnect 617, may be provided periodically across the stack. The local interconnects may be metal-filled slits which extend through the stack, such as to connect the source line/substrate to a line above the stack. The slits may be used during the formation of the word lines and subsequently filled with metal. The local interconnect comprises a conductive region 617a (e.g., metal) within an insulating region 617b. A portion of a bit line BL0 is also depicted. A conductive via 621 connects the drain-end 615 of NS1 to BL0.

In one approach, the block of memory cells comprises a stack of alternating control gate and dielectric layers, and the memory cells are arranged in vertically extending memory holes in the stack.

In one approach, each block comprises a terraced edge in which vertical interconnects connect to each layer, including the SGS, WL and SGD layers, and extend upward to horizontal paths to voltage sources.

This example includes two SGD transistors, two drain side dummy memory cells, two source side dummy memory cells and two SGS transistors in each string, as an example. Generally, the use of dummy memory cells is optional and one or more may be provided. Also, one or more SGD transistors and one or more SGS transistors may be provided in a memory string.

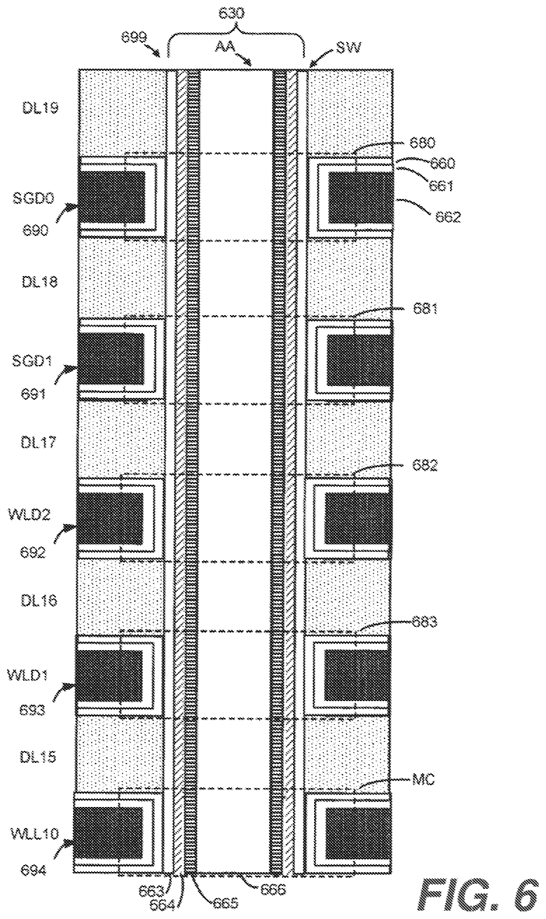

An insulating region 620 may be provided to separate portions of the SGD layers from one another to provide one independently driven SGD line per sub-block. In this example, the word line layers are common to two adjacent sub-blocks. See also FIG. 7B. In another possible implementation, the insulating region 620 extends down to the substrate to separate the word line layers. In this case, the word line layers are separate in each sub-block. Although, in either case, the word line layers of a block can be joined at their ends to one another so that they are commonly driven within a block, as depicted in FIG. 7B.

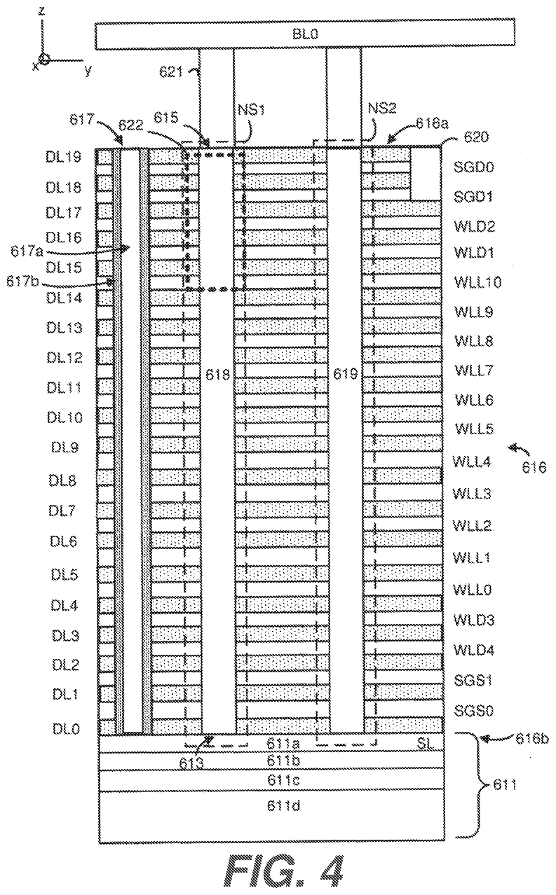

FIG. 5 depicts a plot of memory hole/pillar diameter in the stack of FIG. 4. The vertical axis is aligned with the stack of FIG. 4 and depicts a width (wMH), e.g., diameter, of the pillars formed by materials in the memory holes 618 and 619. In such a memory device, the memory holes which are etched through the stack have a very high aspect ratio. For example, a depth-to-diameter ratio of about 25-30 is common. The memory holes may have a circular cross-section. Due to the etching process, the memory hole and resulting pillar width can vary along the length of the hole. Typically, the diameter becomes progressively smaller from the top to the bottom of the memory hole (solid line). That is, the memory holes are tapered, narrowing at the bottom of the stack. In some cases, a slight narrowing occurs at the top of the hole near the select gate so that the diameter becomes slight wider before becoming progressively smaller from the top to the bottom of the memory hole (long dashed line). For example, the memory hole width is a maximum at the level of WL9 in the stack, in this example. The memory hole width is slightly smaller at the level of WL10, and progressively smaller at the levels of WL8 to WL0.

Due to the non-uniformity in the diameter of the memory hole and resulting pillar, the programming and erase speed of the memory cells can vary based on their position along the memory hole. With a relatively smaller diameter at the bottom of a memory hole, the electric field across the tunnel oxide is relatively stronger, so that the programming and erase speed is higher for memory cells in word lines adjacent to the relatively smaller diameter portion of the memory holes. The amount of word line coupling up and discharge is therefore relatively larger than for memory cells in word lines adjacent to the relatively larger diameter portion of the memory holes.

In another possible implementation, represented by the short dashed line, the stack is fabricated in two tiers. The bottom tier is formed first with a respective memory hole. The top tier is then formed with a respective memory hole which is aligned with the memory hole in the bottom tier. Each memory hole is tapered such that a double tapered memory hole is formed in which the width increases, then decreases and increases again, moving from the bottom of the stack to the top.

FIG. 6 depicts a close-up view of the region 622 of the stack of FIG. 4. Memory cells are formed at the different levels of the stack at the intersection of a word line layer and a memory hole. In this example, SGD transistors 680 and 681 are provided above dummy memory cells 682 and 683 and a data memory cell MC. A number of layers can be deposited along the sidewall (SW) of the memory hole 630 and/or within each word line layer, e.g., using atomic layer deposition. For example, each pillar 699 or column which is formed by the materials within a memory hole can include a charge-trapping layer 663 or film such as silicon nitride (Si₃N₄) or other nitride, a tunneling layer 664 (tunnel oxide), a channel 665 (e.g., comprising polysilicon), and a dielectric core 666. A word line layer can include a blocking oxide/block high-k material 660, a metal barrier 661, and a conductive metal 662 such as Tungsten as a control gate. For example, control gates 690, 691, 692, 693 and 694 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel, and through the tunneling layer. The Vth of a memory cell is increased in proportion to (e.g., with an increase in) the amount of stored charge. During an erase operation, the electrons return to the channel.

Each of the memory holes can be filled with a plurality of annular layers comprising a blocking oxide layer, a charge trapping layer, a tunneling layer and a channel layer. A core region of each of the memory holes is filled with a body material, and the plurality of annular layers are between the core region and the word line in each of the memory holes.

The NAND string can be considered to have a floating body channel because the length of the channel is not formed on a substrate. Further, the NAND string is provided by a plurality of word line layers above one another in a stack, and separated from one another by dielectric layers.

FIG. 7A depicts an example view of NAND strings in sub-blocks in a 3D configuration which is consistent with FIG. 4. Example memory cells are depicted which extend in the x direction along word lines in each sub-block. Each memory cell is depicted as a cube for simplicity. SB0 includes NAND strings 700n, 701n, 702n and 703n. SB1 includes NAND strings 710n, 711n, 712n and 713n. SB2 includes NAND strings 720n, 721n, 722n and 723n. SB3 includes NAND strings 730n, 731n, 732n and 733n. Bit lines are connected to sets of NAND strings. For example, a bit line BL0 is connected to NAND strings 700n, 710n, 720n and 730n, a bit line BL1 is connected to NAND strings 701n, 711n, 721n and 731n, a bit line BL2 is connected to NAND strings 702n, 712n, 722n and 732n, and a bit line BL3 is connected to NAND strings 703n, 713n, 723n and 733n. A sense circuit may be connected to each bit line. For example, sense circuits 400, 400a, 400b and 400c are connected to bit lines BL0, BL1, BL2 and BL3, respectively. The NAND strings are examples of vertical memory strings, e.g., vertical strings, which extend upward from a substrate.

Programming and reading can occur for selected cells in one word line and one sub-block at a time. This allows each selected cell to be controlled by a respective bit line and/or source line. For example, an example set 795 of memory cells in SB0 is connected to WLL4. Similarly, the sets 796, 797 and 798 comprise data memory cells in SB1, SB2 and SB3 are connected to WLL4.

FIG. 7B depicts word line and SGD layers in an example set of blocks which is consistent with FIG. 4. Blocks BLK0, BLK1, BLK2 and BLK3 are depicted. The word line layers (WLL) in each block are depicted and long with example SGD lines. One SGD line is provided in each sub-block. BLK0 includes sub-blocks SB0, SB1, SB2 and SB3. Each circle represents a memory hole or string. The sub-blocks are elongated in the x direction and contain thousands of memory strings in practice. Additionally, many more blocks beyond those depicted are arranged in a row on the substrate. The word line layers and SGD/SGS layers may receive voltages from a row decoder 799.

FIG. 8A depicts an example Vth distribution of memory cells, where eight data states are used, in a first read condition compared to a second read condition. Eight data states are an example only as other numbers may be used such as four, sixteen or more. For the Er, A, B, C, D, E, F and G states, we have Vth distributions 820, 821, 822, 823, 824, 825, 826 and 827, respectively, in the second read condition, and 820a, 821a, 822a, 823a, 824a, 825a, 826a and 827a, respectively, in the first read condition. For the A, B, C, D, E, F and G states, we have program verify voltages VvA, VvB, VvC, VvD, VvE, VvF and VvG, respectively. Also depicted are read voltages VrAH, VrBH, VrCH, VrDH, VrEL, VrFL and VrGL, respectively, in the second read condition, and read voltages VrAL, VrBL, VrCL, VrDL, VrEH, VrFH and VrGH, respectively, in the first read condition. Also depicted is an example encoding of bits of 111, 110, 100, 000, 010, 011, 001 and 101, respectively. The bit format is: UP/MP/LP. An erase verify voltage VvEr is used during an erase operation.

This example indicates the shift in the Vth distribution for the first read condition compared to the second read condition is relatively larger when the data state is relatively lower or higher, than when the data state is mid-range. The shift may be progressively larger for progressively lower or higher data states. In one example, the read voltages of VrAL, VrBL, VrCL and VrDL are optimal for the relatively lower states of A, B, C and D, respectively, and the read voltages of VrEH, VrFH and VrGH are optimal for the relatively higher states of E, F and G, respectively, in the first read condition. Similarly, the read voltages of VrAH, VrBH, VrCH and VrDH are optimal for the relatively lower states of A, B, C and D, respectively, and the read voltages of VrEL, VrFL and VrGL are optimal for the relatively higher states of E, F and G, respectively, in the second read condition. Thus, the lower of two read voltages per state is optimal in the first read condition for the lower states and the higher of two read voltages per state is optimal in the first read condition for the higher states, in one possible implementation.

The optimum read voltages generally are midway between the Vth distributions of adjacent data states. Accordingly, as the Vth distribution shifts, the optimum read voltages shift.

The first read condition can occur when there is a long delay since a last programming or read operation. An example sequence is: program a block, wait for one hour, then read the block. The first read condition can also occur when there is a power down/power up. An example sequence is: program a block, power down/power up, then read the block. The first read condition can also occur when there is a program or read of other blocks. An example sequence is: program one block, program another block, then read the one block.

FIG. 8B depicts example bit sequences for lower, middle and upper pages of data, and associated read voltages. In this case, the memory cells each store three bits of data in one of eight data states. Example bit assignments for each state are depicted. A lower, middle or upper bit can represent data of a lower, middle or upper page, respectively. Seven programmed data states A, B, C, D, E, F and G are used in addition to the erased state, Er. With these bit sequences, the data of the lower page can be determined by reading the memory cells using read voltages (e.g., control gate or word line voltages) of VrA and VrE. The lower page (LP) bit=1 if Vth<=VrA or Vth>VrE. LP=0 if VrA<Vth<=VrE. Generally, a memory cell can be sensed by sense circuitry while a read voltage is applied. If the memory cell is in a conductive state at a sense time, its threshold voltage (Vth) is less than the read voltage. If the memory cell is in a non-conductive state, its Vth is greater than the read voltage.

The read voltages which are used to read a page of data are determined by transitions from 0 to 1 or 1 to 0 in the encoded bits (code word) for each state. For example, the LP bit transitions from 1 to 0 between Er and A, and from 0 to 1 between D and E. Accordingly, the read voltages for the LP are VrA and VrE.

The data of the middle page can be determined by reading the memory cells using read voltages VrB, VrD and VrF. The middle page (MP) bit=1 if Vth<=VrB or VrD<Vth<=VrF. MP=0 if VrB<Vth<=VrD or Vth>VrF. For example, the MP bit transitions from 1 to 0 between A and B, from 0 to 1 between C and D, and from 1 to 0 between E and F. Accordingly, the read voltages for the MP are VrB, VrD and VrF.

The data of the upper page can be determined by reading the memory cells using read voltages of VrC and VrG. The upper page (UP) bit=1 if Vth<=VrC or Vth>VrG. UP=0 if VrC<Vth<=VrG. For example, the UP bit transitions from 1 to 0 between B and C, and from 0 to 1 between F and G. Accordingly, the read voltages for the UP are VrC and VrG. The read voltages are depicted as VrA, VrB, VrC, VrD, VrE, VrF and VrG, where each of these can represent the first or second read values, whichever is optimal.

FIG. 9 depicts a waveform of an example programming operation. The horizontal axis depicts a program loop (PL) number and the vertical axis depicts control gate or word line voltage. Generally, a programming operation can involve applying a pulse train to a selected word line, where the pulse train includes multiple program loops or program-verify iterations. The program portion of the program-verify iteration comprises a program voltage, and the verify portion of the program-verify iteration comprises one or more verify voltages.

Each program voltage includes two steps, in one approach. Further, Incremental Step Pulse Programming (ISPP) is used in this example, in which the program voltage steps up in each successive program loop using a fixed or varying step size. This example uses ISPP in a single programming pass in which the programming is completed. ISPP can also be used in each programming pass of a multi-pass operation.

The waveform 900 includes a series of program voltages 901, 902, 903, 904, 905, . . . 906 that are applied to a word line selected for programming and to an associated set of non-volatile memory cells. One or more verify voltages can be provided after each program voltage as an example, based on the target data states which are being verified. 0 V may be applied to the selected word line between the program and verify voltages. For example, A- and B-state verify voltages of VvA and VvB, respectively, (waveform 910) may be applied after each of the program voltages 901 and 902. A-, B- and C-state verify voltages of VvA, VvB and VvC (waveform 911) may be applied after each of the program voltages 903 and 904. After several additional program loops, not shown, E-, F- and G-state verify voltages of VVE, VvF and VvG (waveform 912) may be applied after the final program voltage 906.

As discussed, program disturb during a program operation can adversely affect memory cell reliability, especially for QLC and PLC memory devices or apparatuses. More specifically, as multi-level-cell technology develops, the program threshold voltage budget becomes more limited as the number of data states increases, such as with quad-level cells QLC (16 states) and five-level cells PLC (32 states). Furthermore, QLC/PLC may utilize a comparatively higher number of program loops during a program operation, which leads to an increase in program disturb for lower states (i.e., those associated with relatively lower threshold voltages) causing the threshold voltage budget to be further degraded. FIG. 10 shows threshold voltage distributions for quad-level cells after an erase operation (distribution 1000), after programming (distribution 1002), and after a bit-level erase operation (distribution 1004), discussed in more detail below. Distribution 1000 illustrates the erase or S0 state threshold voltage distribution after erase, but when the QLC program operation is finished, the threshold voltage distribution of the S0 state will be disturbed much higher and the S0-S1 threshold voltage budget becomes much smaller, as shown in distribution 1002, which significantly impacts the cell reliability performance.

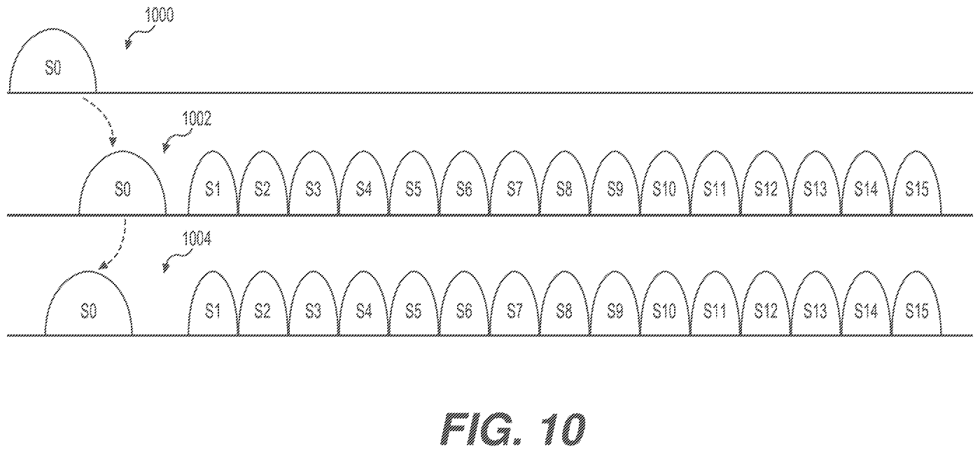

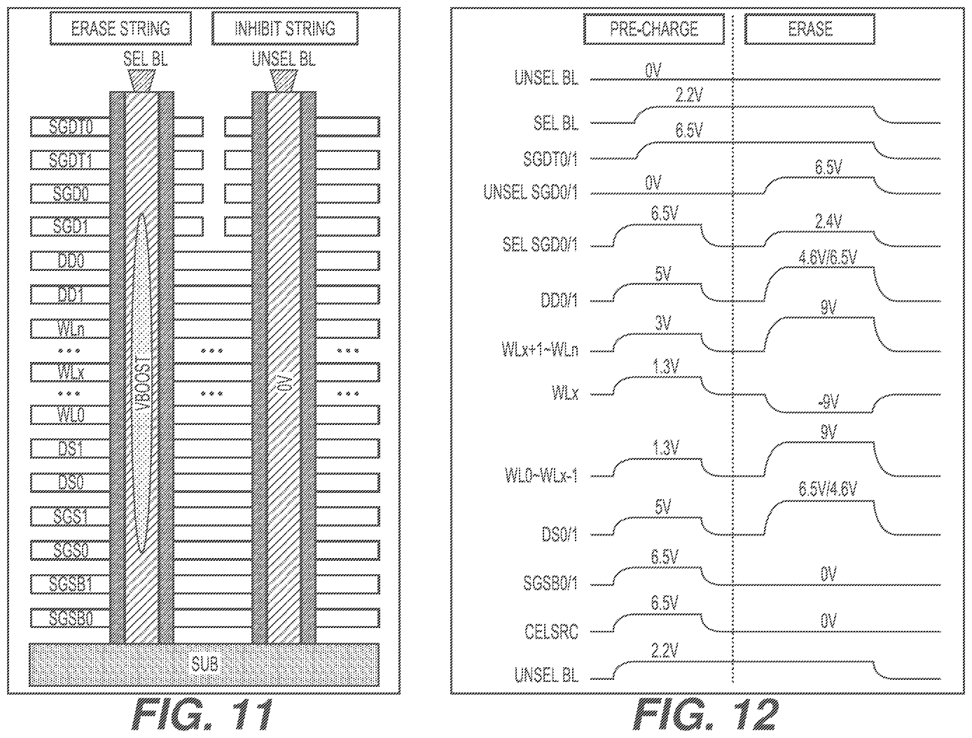

Consequently, described herein is a memory apparatus (e.g., memory device 100 in FIG. 1A) including memory cells (e.g., memory cell 200 in FIG. 1B). Each of the memory cells is connected to one of a plurality of word lines (e.g., WLL0-WLL10 in FIG. 4) and is configured to retain a threshold voltage Vt or Vth. The apparatus also includes a control means (e.g., control circuitry 110, controller 122, row decoder 124, source control circuits 127, read/write circuits 128, sense blocks 51, 52, 53, and column decoder 132 in FIG. 1A) coupled to the plurality of word lines and configured to apply at least one programming pulse of a program voltage to selected ones of the plurality of word lines during at least one programming loop of a programming operation. The control means is also configured to reduce the threshold voltage of the memory cells targeted for an erased state during a bit-level erase operation following the programming operation. According to an aspect, the memory cells are each configured to store four or more bits. So, when the program operation is finished, the bit-level erase operation is appended to erase S0 state cells (i.e., memory cells targeted for the erased state) lower and achieve more S0-S1 threshold budget, as shown in the distribution 1004 of FIG. 10. FIG. 11 shows a cross-sectional view of a portion of an example memory apparatus and illustrates voltages in a channel of a string or memory hole including the memory cells targeted for the erased state (i.e., erase string) and another memory hole including the memory cells not targeted for the erased state (i.e., inhibit string). FIG. 12 shows voltage levels and timing during the bit-level erase operation and pre-charging preceding the bit-level erase operation for the bit lines, word lines, and select gate transistors, for example (all voltages in FIG. 12 are approximate values). In addition, it should be understood that other voltage levels besides those shown and discussed are contemplated.

Referring back to FIG. 4, for example, the memory cells may be disposed in memory holes (e.g., NAND strings NS0 and NS1). The memory holes are each connected to one of a plurality of bit lines (e.g., bit line BL0) coupled to the control means. The plurality of word lines and a plurality of dielectric layers (e.g., dielectric layers DL0-DL19) extend horizontally and overlay one another in an alternating fashion in a stack. The memory holes extend vertically through the stack. The memory cells are connected in series between at least one drain-side select gate transistor (e.g., at SGD layers) on a drain-side of each of the memory holes and at least one source-side select gate transistor (e.g., at SGS layers) on a source-side of each of the memory holes. The drain-side select gate transistor of each of the memory holes is connected to one of the plurality of bit lines and the source-side select gate transistor of each of the memory holes is connected to a source line (e.g., source line SL). Thus, according to an aspect and referring back to FIG. 12, the control means is further configured, during the bit-level erase operation, to apply a supply voltage VDDSA (e.g., 2.2 volts) to selected ones of the plurality of bit lines (Sel BL) while applying a transistor threshold voltage VSGD (e.g., 2.4 volts) to the at least one drain-side select gate transistor (Sel SGD0/1) of each of the memory holes including the memory cells targeted for the erased state and applying a steady state voltage VSS (e.g., 0 volts) to the at least one source-side select gate transistor (SGS 0/1) of each of the memory holes including the memory cells targeted for the erased state. So, the SGD/SGS turn off and the channel of the memory hole becomes floating for the erase string. According to an aspect, the erase bias is a negative voltage (e.g.,-9 volts). The control means is additionally configured, during the bit-level erase operation, to apply a pass voltage VPASS (e.g., 9 volts) to unselected ones of the plurality of word lines (WLx+1˜WLn and WL0˜WLx−1). Therefore, during the voltage ramping from 0V to VPASS for the unselected ones of the plurality of word lines, the channel will be coupled to Vboost (˜9V). The control means is also configured, during the bit-level erase operation, to apply an erase bias to each of the plurality of word lines WLx connected to the memory cells targeted for the erased state. Thus, the memory cell in the erase string will be erased by the strong stress (˜18V).

According to additional aspects of the disclosure and continuing to refer to FIG. 12, the control means is further configured, during the bit-level erase operation, to apply a steady state voltage VSS (e.g., 0 volts) to unselected ones of the plurality of bit lines (Unsel BL) while applying a read pass voltage VREAD (e.g., 6.5 volts) to the at least one drain-side select gate transistor (Unsel SGD0/1) of each of the memory holes including the memory cells not targeted for the erased state and applying the steady state voltage VSS to the at least one source-side select gate transistor (SGS0/1) of each of the memory holes including the memory cells not targeted for the erased state. So, then SGD turns on and SGS turns off. The control means is also configured, during the bit-level erase operation, to apply the pass voltage VPASS (e.g., 9 volts) to unselected ones of the plurality of word lines (WLx+1˜WLn and WL0˜WLx−1). Thus, during the voltage ramping from 0V to VPASS, no boosting happens in the channel and the channel potential remains the same as the bit line voltage of inhibit string. The control means is additionally configured, during the bit-level erase operation, to apply the erase bias (e.g., −9 volts) to each of the plurality of word lines connected to the memory cells targeted for the erased state WLx. Therefore, the memory cell in the inhibit string will be inhibited and protected from being erased by the weak stress (˜ 9V). The other non-data WLs (e.g., DD0/1 and DS)/1) can be biased as in a normal program operation.

Again, the threshold voltage corresponds to one of a plurality of data states (e.g., “Er”, “A”, “B”, “C”, “D”, “E”, “F” and “G” in FIG. 8A or S0, S1, S2, S3, S4, S5, S6, S7, S8, S9, S10, S11, S12, S13, S14 and S15 data states of FIG. 10), the at least one programming loop includes a plurality of programming loops, and the at least one programming pulse includes a plurality of programming pulses. Thus, according to aspects of the disclosure, the control means is further configured to start the programming operation and initialize a loop count of the plurality of programming pulses. The control means is also configured to apply one of the plurality of programming pulses of the program voltage to selected ones of the plurality of word lines while applying a pass voltage to unselected ones of the plurality of word lines during one of the plurality of programming loops of the programming operation. The control means is additionally configured to apply verification pulses of a plurality of program verify voltages each associated with one of the plurality of data states to the selected ones of the plurality of word lines to determine whether the memory cells have the threshold voltage below each of the plurality of program verify voltages targeted for each of the memory cells being programmed during each of a plurality of verify loops during the programming operation. In addition, the control means is configured to determine whether the memory cells targeted for all of the plurality of data states pass verify based on a count of the memory cells targeted for the each of the plurality of data states below each of the plurality of program verify voltages targeted for each of the memory cells being programmed being less than a predetermined count threshold. The control means determines the programming operation to be complete in response to determining the memory cells targeted for all of the plurality of data states pass verify. The control means is further configured to reduce the threshold voltage of the memory cells targeted for the erased state during the bit-level erase operation in response to determining the programming operation to be complete. The control means determines whether the loop count is less than or equal to a predetermined maximum loop count in response to determining the memory cells targeted for all of the plurality of data states do not pass verify. In addition, the control means is configured to determine the programming operation to be failed in response to determining the loop count is not less than or equal to the predetermined maximum loop count. The control means is also configured to increase the program voltage by a program step amount and increment the loop count of the plurality of programming loops and return to apply one of the plurality of programming pulses of the program voltage to selected ones of the plurality of word lines while applying the pass voltage to unselected ones of the plurality of word lines during one of the plurality of programming loops of the programming operation in response to determining the loop count is less than or equal to the predetermined maximum loop count.

The bit-level erase operation appended at the end of a program operation described herein advantageously improves the threshold voltage budget, especially when using advanced multi-level-cell programming (e.g., QLC or PLC memory cells), which suffers significant program disturb due to more program loops compared to triple-level memory cells, for example. The bit-level erase operation will increase program time tProg. However, the bit-level erase operation may be carried out by softly erasing memory cells targeted for the Erased state deeper (lower threshold voltage), which can include one erase pulse. Thus, according to another aspect, the control means is further configured to apply a single erase pulse of an erase bias to each of the plurality of word lines connected to the memory cells targeted for the erased state during the bit-level erase operation following the programming operation. Furthermore, the erase pulse width of the bit-level erase operation can be much smaller than the normal erase. And the erase bias or negative erase voltage may also be increased in magnitude to improve erase efficiency and to exchange for a shorter erase pulse width. The program time tPROG for PLC may, for example, be millisecond level, so an extra appended bit level erase operation timing will be negligible.

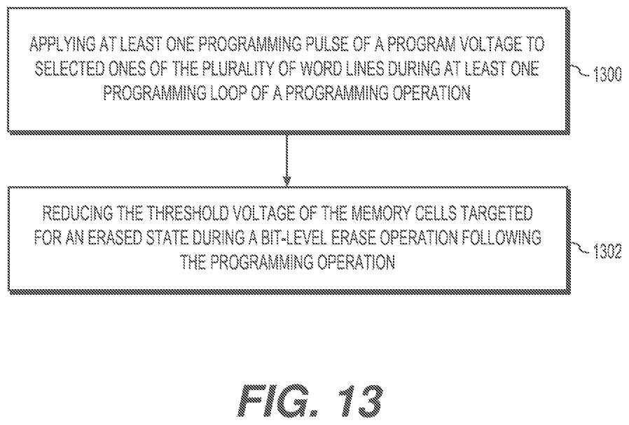

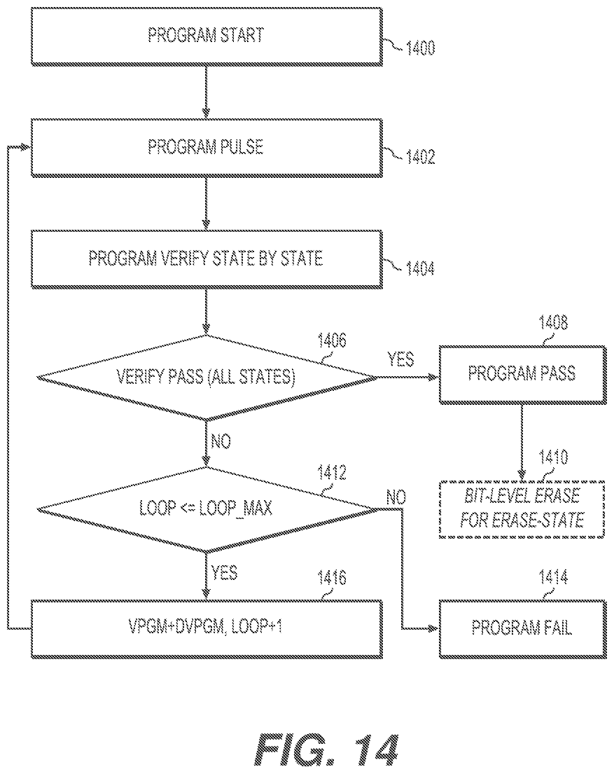

Now referring to FIGS. 13 and 14, a method of operating a memory apparatus is also provided. As discussed above, the memory apparatus includes memory cells (e.g., memory cell 200 in FIG. 1B). Each of the memory cells is connected to one of a plurality of word lines (e.g., WLL0-WLL10 in FIG. 4) and is configured to retain a threshold voltage Vth corresponding to one of a plurality of data states (e.g., “Er”, “A”, “B”, “C”, “D”, “E”, “F” and “G” in FIG. 8A or S0, S1, S2, S3, S4, S5, S6, S7, S8, S9, S10, S11, S12, S13, S14 and S15 data states of FIG. 10). So, referring initially to FIG. 13, the method includes the step of 1300 applying at least one programming pulse of a program voltage to selected ones of the plurality of word lines during at least one programming loop of a programming operation. The method also includes the step of 1302 reducing the threshold voltage of the memory cells targeted for an erased state during a bit-level erase operation following the programming operation. As above, according to an aspect, the memory cells are each configured to store four or more bits.

Once again, referring back to FIG. 4, for example, the memory cells may be disposed in memory holes (e.g., NAND strings NS0 and NS1). The memory holes are each connected to one of the plurality of bit lines (e.g., bit line BL0) coupled to the control means. The plurality of word lines and the plurality of dielectric layers (e.g., dielectric layers DL0-DL19) extend horizontally and overlay one another in an alternating fashion in a stack. The memory holes extend vertically through the stack. The memory cells are connected in series between the at least one drain-side select gate transistor (e.g., at SGD layers) on the drain-side of each of the memory holes and the at least one source-side select gate transistor (e.g., at SGS layers) on the source-side of each of the memory holes. The drain-side select gate transistor of each of the memory holes is connected to one of the plurality of bit lines and the source-side select gate transistor of each of the memory holes is connected to the source line (e.g., source line SL). Thus, according to an aspect and referring back to FIG. 12, method further includes the step of, during the bit-level erase operation, applying a supply voltage VDDSA (e.g., 2.2 volts) to selected ones of the plurality of bit lines (Sel BL) while applying a transistor threshold voltage VSGD (e.g., 2.4 volts) to the at least one drain-side select gate transistor (Sel SGD0/1) of each of the memory holes including the memory cells targeted for the erased state and applying a steady state voltage VSS (e.g., 0 volts) to the at least one source-side select gate transistor (SGS 0/1) of each of the memory holes including the memory cells targeted for the erased state. Again, according to an aspect, the erase bias is a negative voltage (e.g., −9 volts). The method also includes the step of, during the bit-level erase operation, applying a pass voltage VPASS (e.g., 9 volts) to unselected ones of the plurality of word lines (WLx+1˜WLn and WL0˜WLx−1). The method additionally includes the step of, during the bit-level erase operation, applying an erase bias to each of the plurality of word lines WLx connected to the memory cells targeted for the erased state.

As above, according to additional aspects of the disclosure and continuing to refer to FIG. 12, the method continues with the step of, during the bit-level erase operation, applying a steady state voltage VSS (e.g., 0 volts) to unselected ones of the plurality of bit lines (Unsel BL) while applying a read pass voltage VREAD (e.g., 6.5 volts) to the at least one drain-side select gate transistor (Unsel SGD0/1) of each of the memory holes including the memory cells not targeted for the erased state and applying the steady state voltage VSS to the at least one source-side select gate transistor (SGS0/1) of each of the memory holes including the memory cells not targeted for the erased state. The method proceeds with the step of, during the bit-level erase operation, applying the pass voltage VPASS (e.g., 9 volts) to unselected ones of the plurality of word lines (WLx+1˜WLn and WL0˜WLx−1). In addition, the method includes the step of, during the bit-level erase operation, applying the erase bias (e.g., −9 volts) to each of the plurality of word lines connected to the memory cells targeted for the erased state WLx. Again, the other non-data WLs (e.g., DD0/1 and DS)/1) can be biased as in a normal program operation.

Again, the threshold voltage corresponds to one of a plurality of data states (e.g., “Er”, “A”, “B”, “C”, “D”, “E”, “F” and “G” in FIG. 8A or S0, S1, S2, S3, S4, S5, S6, S7, S8, S9, S10, S11, S12, S13, S14 and S15 data states of FIG. 10). The at least one programming loop can include the plurality of programming loops and the at least one programming pulse may include a plurality of programming pulses. Thus, referring specifically to FIG. 14 and according to aspects of the disclosure, the method further includes the step of 1400 starting the programming operation and initializing a loop count of the plurality of programming pulses. Next, 1402 applying one of the plurality of programming pulses of the program voltage to selected ones of the plurality of word lines while applying a pass voltage to unselected ones of the plurality of word lines during one of the plurality of programming loops of the programming operation. The method proceeds with the step of 1404 applying verification pulses of a plurality of program verify voltages each associated with one of the plurality of data states to the selected ones of the plurality of word lines to determine whether the memory cells have the threshold voltage below each of the plurality of program verify voltages targeted for each of the memory cells being programmed during each of a plurality of verify loops during the programming operation. The method additionally includes the step of 1406 determining whether the memory cells targeted for all of the plurality of data states pass verify based on a count of the memory cells targeted for the each of the plurality of data states below each of the plurality of program verify voltages targeted for each of the memory cells being programmed being less than a predetermined count threshold. The method continues by 1408 determining the programming operation to be complete in response to determining the memory cells targeted for all of the plurality of data states pass verify. The next step of the method is 1410 reducing the threshold voltage of the memory cells targeted for the erased state during the bit-level erase operation in response to determining the programming operation to be complete. Next, 1412 determining whether the loop count is less than or equal to a predetermined maximum loop count in response to determining the memory cells targeted for all of the plurality of data states do not pass verify. In addition, the method includes the step of 1414 determining the programming operation to be failed in response to determining the loop count is not less than or equal to the predetermined maximum loop count. The method also includes the step of 1416 increasing the program voltage by a program step amount and incrementing the loop count of the plurality of programming loops and return to applying one of the plurality of programming pulses of the program voltage to selected ones of the plurality of word lines while applying the pass voltage to unselected ones of the plurality of word lines during one of the plurality of programming loops of the programming operation in response to determining the loop count is less than or equal to the predetermined maximum loop count.

According to a further aspect and as mentioned above, the erase bias may be applied using a single pulse. Thus, the method can further include the step of applying a single erase pulse of an erase bias to each of the plurality of word lines connected to the memory cells targeted for the erased state during the bit-level erase operation following the programming operation.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptions used herein interpreted accordingly.

What is claimed is:

1. A memory apparatus, comprising:
memory cells each connected to one of a plurality of word lines and configured to store a threshold voltage; and
a control means coupled to the plurality of word lines and configured to:
apply at least one programming pulse of a program voltage to selected ones of the plurality of word lines during at least one programming loop of a programming operation, and
reduce the threshold voltage of the memory cells targeted for an erased state during a bit-level erase operation following the programming operation.

2. The memory apparatus as set forth in claim 1, wherein the memory cells are disposed in a memory holes, the memory holes are each connected to one of a plurality of bit lines coupled to the control means, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the control means is further configured, during the bit-level erase operation, to:
apply a supply voltage to selected ones of the plurality of bit lines while applying a transistor threshold voltage to the at least one drain-side select gate transistor of each of the memory holes including the memory cells targeted for the erased state and applying a steady state voltage to the at least one source-side select gate transistor of each of the memory holes including the memory cells targeted for the erased state;
apply an erase bias to each of the plurality of word lines connected to the memory cells targeted for the erased state; and
apply a pass voltage to unselected ones of the plurality of word lines.

3. The memory apparatus as set forth in claim 2, wherein the erase bias is a negative voltage.

4. The memory apparatus as set forth in claim 1, wherein the memory cells are disposed in memory holes, the memory holes are each connected to one of a plurality of bit lines coupled to the control means, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the control means is further configured, during the bit-level erase operation, to:
apply a steady state voltage to unselected ones of the plurality of bit lines while applying a read pass voltage to the at least one drain-side select gate transistor of each of the memory holes including the memory cells not targeted for the erased state and applying the steady state voltage VSS to the at least one source-side select gate transistor of each of the memory holes including the memory cells not targeted for the erased state;
apply an erase bias to each of the plurality of word lines connected to the memory cells targeted for the erased state; and
apply a pass voltage to unselected ones of the plurality of word lines.

5. The memory apparatus as set forth in claim 1, wherein the control means is further configured to apply a single erase pulse of an erase bias to each of the plurality of word lines connected to the memory cells targeted for the erased state during the bit-level erase operation following the programming operation.

6. The memory apparatus as set forth in claim 1, wherein the threshold voltage corresponds to one of a plurality of data states, the at least one programming loop includes a plurality of programming loops, the at least one programming pulse includes a plurality of programming pulses, and the control means is further configured to:
start the programming operation and initialize a loop count of the plurality of programming pulses;
apply one of the plurality of programming pulses of the program voltage to selected ones of the plurality of word lines while applying a pass voltage to unselected ones of the plurality of word lines during one of the plurality of programming loops of the programming operation;
apply verification pulses of a plurality of program verify voltages each associated with one of the plurality of data states to the selected ones of the plurality of word lines to determine whether the memory cells have the threshold voltage below each of the plurality of program verify voltages targeted for each of the memory cells being programmed during each of a plurality of verify loops during the programming operation;
determine whether the memory cells targeted for all of the plurality of data states pass verify based on a count of the memory cells targeted for the each of the plurality of data states below each of the plurality of program verify voltages targeted for each of the memory cells being programmed being less than a predetermined count threshold;
determine the programming operation to be complete in response to determining the memory cells targeted for all of the plurality of data states pass verify;
reduce the threshold voltage of the memory cells targeted for the erased state during the bit-level erase operation in response to determining the programming operation to be complete;
determine whether the loop count is less than or equal to a predetermined maximum loop count in response to determining the memory cells targeted for all of the plurality of data states do not pass verify;
determine the programming operation to be failed in response to determining the loop count is not less than or equal to the predetermined maximum loop count; and
increase the program voltage by a program step amount and increment the loop count of the plurality of programming loops and return to apply one of the plurality of programming pulses of the program voltage to selected ones of the plurality of word lines while applying the pass voltage to unselected ones of the plurality of word lines during one of the plurality of programming loops of the programming operation in response to determining the loop count is less than or equal to the predetermined maximum loop count.

7. The memory apparatus as set forth in claim 1, wherein the memory cells are each configured to store four or more bits.

8. A controller in communication with a memory apparatus including a plurality of memory cells each connected to one of a plurality of word lines and configured to store a threshold voltage, the controller configured to:
instruct the memory apparatus to apply at least one programming pulse of a program voltage to selected ones of the plurality of word lines during at least one programming loop of a programming operation; and
instruct the memory apparatus to reduce the threshold voltage of the memory cells targeted for an erased state during a bit-level erase operation following the programming operation.

9. The controller as set forth in claim 8, wherein the memory cells are disposed in memory holes, the memory holes are each connected to one of a plurality of bit lines, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the controller is further configured, during the bit-level erase operation, to:
instruct the memory apparatus to apply a supply voltage to selected ones of the plurality of bit lines while applying a transistor threshold voltage to the at least one drain-side select gate transistor of each of the memory holes including the memory cells targeted for the erased state and applying a steady state voltage VSS to the at least one source-side select gate transistor of each of the memory holes including the memory cells targeted for the erased state;
instruct the memory apparatus to apply an erase bias to each of the plurality of word lines connected to the memory cells targeted for the erased state; and
instruct the memory apparatus to apply a pass voltage to unselected ones of the plurality of word lines.

10. The controller as set forth in claim 9, wherein the erase bias is a negative voltage.

11. The controller as set forth in claim 8, wherein the memory cells are disposed in memory holes, the memory holes are each connected to one of a plurality of bit lines, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the controller is further configured, during the bit-level erase operation, to:
instruct the memory apparatus to apply a steady state voltage to unselected ones of the plurality of bit lines while applying a read pass voltage to the at least one drain-side select gate transistor of each of the memory holes including the memory cells not targeted for the erased state and applying the steady state voltage VSS to the at least one source-side select gate transistor of each of the memory holes including the memory cells not targeted for the erased state;
instruct the memory apparatus to apply an erase bias to each of the plurality of word lines connected to the memory cells targeted for the erased state; and
instruct the memory apparatus to apply a pass voltage to unselected ones of the plurality of word lines.

12. The controller as set forth in claim 8, wherein the controller is further configured to instruct the memory apparatus to apply a single erase pulse of an erase bias to each of the plurality of word lines connected to the memory cells targeted for the erased state during the bit-level erase operation following the programming operation.

13. The controller as set forth in claim 8, wherein the threshold voltage corresponds to one of a plurality of data states, the at least one programming loop includes a plurality of programming loops, the at least one programming pulse includes a plurality of programming pulses, and the controller is further configured to:
start the programming operation and initialize a loop count of the plurality of programming pulses;
instruct the memory apparatus to apply one of the plurality of programming pulses of the program voltage to selected ones of the plurality of word lines while applying a pass voltage to unselected ones of the plurality of word lines during one of the plurality of programming loops of the programming operation;
instruct the memory apparatus to apply verification pulses of a plurality of program verify voltages each associated with one of the plurality of data states to the selected ones of the plurality of word lines to determine whether the memory cells have the threshold voltage below each of the plurality of program verify voltages targeted for each of the memory cells being programmed during each of a plurality of verify loops during the programming operation;
determine whether the memory cells targeted for all of the plurality of data states pass verify based on a count of the memory cells targeted for the each of the plurality of data states below each of the plurality of program verify voltages targeted for each of the memory cells being programmed being less than a predetermined count threshold;
determine the programming operation to be complete in response to determining the memory cells targeted for all of the plurality of data states pass verify;
instruct the memory apparatus to reduce the threshold voltage of the memory cells targeted for the erased state during the bit-level erase operation in response to determining the programming operation to be complete;
determine whether the loop count is less than or equal to a predetermined maximum loop count in response to determining the memory cells targeted for all of the plurality of data states do not pass verify;
determine the programming operation to be failed in response to determining the loop count is not less than or equal to the predetermined maximum loop count; and
instruct the memory apparatus to increase the program voltage by a program step amount and increment the loop count of the plurality of programming loops and return to apply one of the plurality of programming pulses of the program voltage to selected ones of the plurality of word lines while applying the pass voltage to unselected ones of the plurality of word lines during one of the plurality of programming loops of the programming operation in response to determining the loop count is less than or equal to the predetermined maximum loop count.

14. A method of operating a memory apparatus including memory cells each connected to one of a plurality of word lines and configured to store a threshold voltage; the method comprising the steps of:
applying at least one programming pulse of a program voltage to selected ones of the plurality of word lines during at least one programming loop of a programming operation; and
reducing the threshold voltage of the memory cells targeted for an erased state during a bit-level erase operation following the programming operation.

15. The method as set forth in claim 14, wherein the memory cells are disposed in memory holes, the memory holes are each connected to one of a plurality of bit lines, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the method further includes the steps of, during the bit-level erase operation:
applying a supply voltage to selected ones of the plurality of bit lines while applying a transistor threshold voltage to the at least one drain-side select gate transistor of each of the memory holes including the memory cells targeted for the erased state and applying a steady state voltage to the at least one source-side select gate transistor of each of the memory holes including the memory cells targeted for the erased state;
applying an erase bias to each of the plurality of word lines connected to the memory cells targeted for the erased state; and
applying a pass voltage to unselected ones of the plurality of word lines.

16. The method as set forth in claim 15, wherein the erase bias is a negative voltage.

17. The method as set forth in claim 14, wherein the memory cells are disposed in memory holes, the memory holes are each connected to one of a plurality of bit lines, the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the drain-side select gate transistor of each of the memory holes is connected to one of the plurality of bit lines and the source-side select gate transistor of each of the memory holes is connected to a source line, the method further includes the steps of, during the bit-level erase operation:
applying a steady state voltage to unselected ones of the plurality of bit lines while applying a read pass voltage to the at least one drain-side select gate transistor of each of the memory holes including the memory cells not targeted for the erased state and applying the steady state voltage to the at least one source-side select gate transistor of each of the memory holes including the memory cells not targeted for the erased state;
applying an erase bias to each of the plurality of word lines connected to the memory cells targeted for the erased state; and
applying a pass voltage to unselected ones of the plurality of word lines.

18. The method as set forth in claim 14, further including the step of applying a single erase pulse of an erase bias to each of the plurality of word lines connected to the memory cells targeted for the erased state during the bit-level erase operation following the programming operation.

19. The method as set forth in claim 14, wherein the threshold voltage corresponds to one of a plurality of data states, the at least one programming loop includes a plurality of programming loops, the at least one programming pulse includes a plurality of programming pulses, and the method further includes the steps of:
starting the programming operation and initializing a loop count of the plurality of programming pulses;
applying one of the plurality of programming pulses of the program voltage to selected ones of the plurality of word lines while applying a pass voltage to unselected ones of the plurality of word lines during one of the plurality of programming loops of the programming operation;
applying verification pulses of a plurality of program verify voltages each associated with one of the plurality of data states to the selected ones of the plurality of word lines to determine whether the memory cells have the threshold voltage below each of the plurality of program verify voltages targeted for each of the memory cells being programmed during each of a plurality of verify loops during the programming operation;
determining whether the memory cells targeted for all of the plurality of data states pass verify based on a count of the memory cells targeted for the each of the plurality of data states below each of the plurality of program verify voltages targeted for each of the memory cells being programmed being less than a predetermined count threshold;
determining the programming operation to be complete in response to determining the memory cells targeted for all of the plurality of data states pass verify;
reducing the threshold voltage of the memory cells targeted for the erased state during the bit-level erase operation in response to determining the programming operation to be complete;
determining whether the loop count is less than or equal to a predetermined maximum loop count in response to determining the memory cells targeted for all of the plurality of data states do not pass verify;
determining the programming operation to be failed in response to determining the loop count is not less than or equal to the predetermined maximum loop count; and
increasing the program voltage by a program step amount and incrementing the loop count of the plurality of programming loops and return to applying one of the plurality of programming pulses of the program voltage to selected ones of the plurality of word lines while applying the pass voltage to unselected ones of the plurality of word lines during one of the plurality of programming loops of the programming operation in response to determining the loop count is less than or equal to the predetermined maximum loop count.

20. The method as set forth in claim 14, wherein the memory cells are each configured to store four or more bits.
